(19) United States
(12) Patent Application Publication
(10) Pub. No.: US 2019/0271079 A1
(43) Pub. Date: Sep. 5, 2019

(54) VAPORIZER AND VAPORIZED GAS SUPPLY UNIT

(71) Applicant: Toshiba Memory Corporation, Minato-ku (JP)

(72) Inventors: Mari Kusunoki, Yokkaichi (JP); Shinji Miyazaki, Kawagoe (JP)

(73) Assignee: Toshiba Memory Corporation, Minato-ku (JP)

(21) Appl. No.: 16/032,128

(22) Filed: Jul. 11, 2018

(30) Foreign Application Priority Data
Mar. 5, 2018 (JP) 2018-038302

(51) Int. Cl. C23C 16/448; C23C 16/44

(52) U.S. Cl. CPC C23C 16/4481; C23C 16/4408; C23C 16/4402

(57) ABSTRACT

A vaporizer according to one embodiment includes: a charging unit in which solid feedstock that generates a vaporized gas can be charged; and a vaporized gas extraction unit that is provided at a bottom portion of the charging unit in a manner communicable with the charging unit and extracts the vaporized gas generated by heating the solid feedstock.

### CROSS-REFERENCE TO RELATED APPLICATIONS

This application is based upon and claims the benefit of priority from Japanese Patent Application No. 2010-038302, filed on Mar. 5, 2018; the entire contents of which are incorporated herein by reference.

### FIELD

Embodiments of the present invention described herein relate generally to a vaporizer and a vaporized gas supply unit.

### BACKGROUND

In a step of manufacturing a semiconductor device, there may be a case where solid feedstock charged into a vaporizer is vaporized and supplied to a substrate processing apparatus, and the substrate is processed with the supplied vaporized gas. In this case, it is desirable to stably vaporize the solid feedstock and improve consumption efficiency of the solid feedstock inside the vaporizer.

### BRIEF DESCRIPTION OF THE DRAWINGS

FIG. 1 is a diagram illustrating an exemplary structure of a vaporizer according to a first embodiment;

FIG. 2 is a diagram illustrating an external view of the vaporizer according to the first embodiment; and

FIG. 3 is a diagram illustrating an exemplary structure of a vaporizer according to a second embodiment.

### DETAILED DESCRIPTION

A vaporizer according to one embodiment includes: a charging unit in which solid feedstock that generates a vaporized gas can be charged; and a vaporized gas extraction unit that is provided at a bottom portion of the charging unit in a manner communicable with the charging unit and extracts the vaporized gas generated by heating the solid feedstock.

Hereinafter, the present invention will be described in detail with reference to the drawings. Note that the present invention is not limited to the following embodiments. Additionally, constituent elements in the following embodiments include the constituent elements easily conceivable by a man skilled in the art or the constituent elements substantially the same.

### First Embodiment

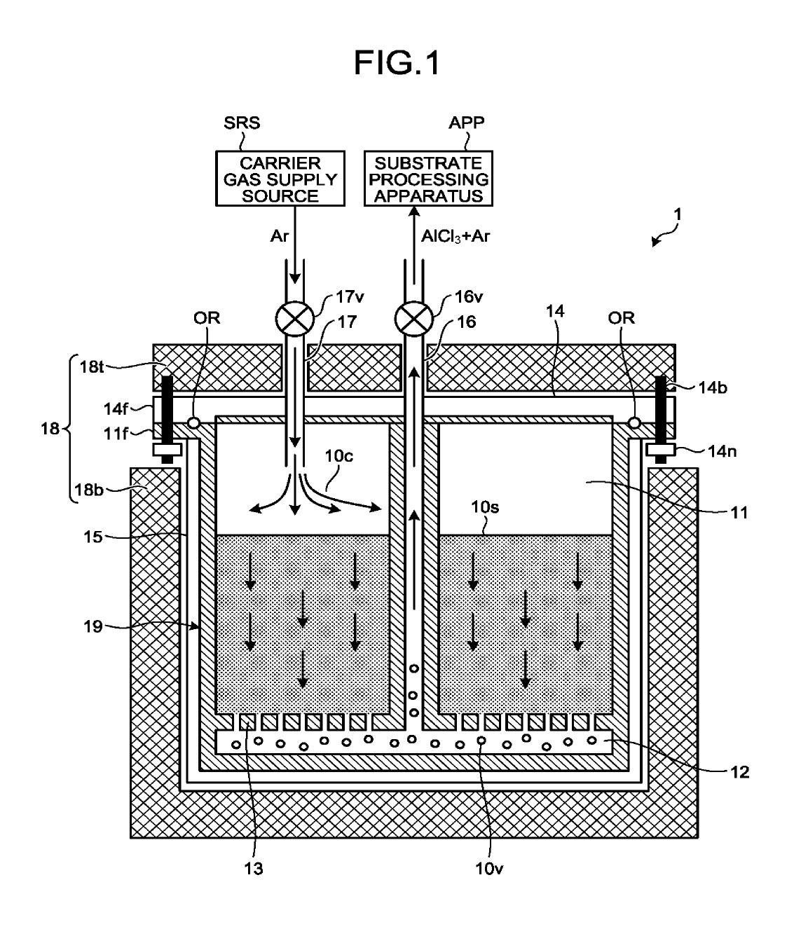

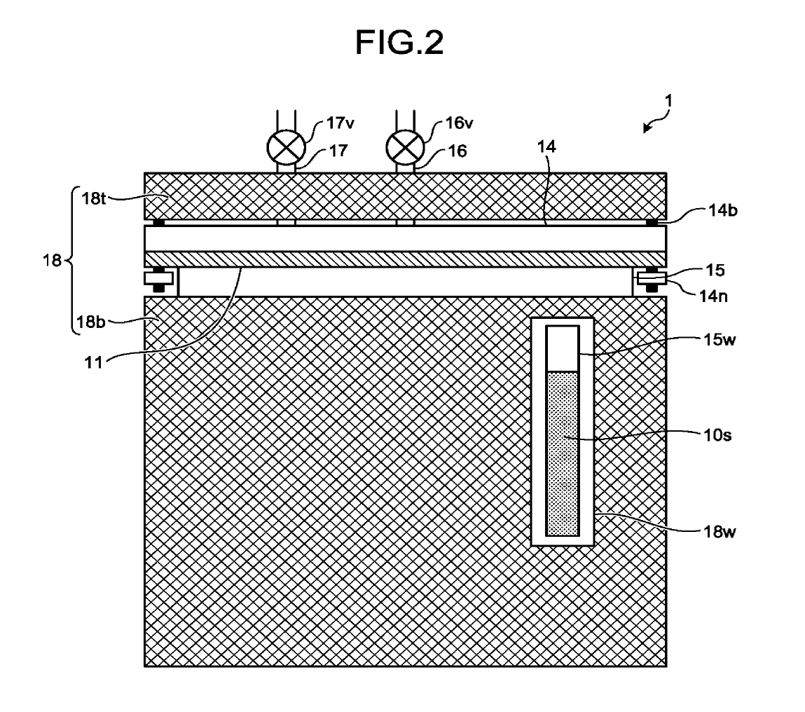

A vaporizer 1 of a first embodiment will be described with reference to FIGS. 1 and 2.

FIG. 1 is a diagram illustrating an exemplary structure of the vaporizer 1 according to the first embodiment. As illustrated in FIG. 1, the vaporizer 1 includes a cylindrical tank 19 having a bottom surface, for example. The tank 19 includes a charging unit 11 and a vaporized gas extraction unit 12, which are separated by a dispersion plate 13.

The charging unit 11 is a space in which solid feedstock 10s that generates a vaporized gas 10v can be charged. Specifically, the charging unit 11 is defined as a space partitioned by the tank 19, the dispersion plate 13, and an upper lid 14 described later. More specifically, the charging unit 11 is partitioned into a cylindrical shape in which, for example, the upper lid 14 is arranged at an upper portion and the dispersion plate 13 is arranged at a bottom portion. A lower flange 11f is provided at a portion corresponding to an upper edge of the cylindrical shape. The lower flange 11f is made to contact an upper flange 14f of the upper lid 14 that covers an open portion of the charging unit 11 via an O-ring OR. The lower flange 11f and the upper flange 14f made to contact each other are fixed by, for example, a bolt 14b, a nut 14n, and the like. In the charging unit 11, for example, about several liters of powdery solid feedstock 10s can be charged into the cylindrical shape covered with the upper lid 14. The solid feedstock 10s is, for example, AlCl₃. In the charging unit 11, the solid feedstock 10s is charged to a predetermined height from the dispersion plate 13 at the bottom portion, and the solid feedstock 10s is not charged in a space higher than the predetermined height (hereinafter also referred to as an upper space). In the upper space of the charging unit 11, for example, a kind of gas same as a carrier gas 10c described later is enclosed.

The vaporized gas extraction unit 12 is a space provided at the bottom portion of the charging unit 11 in a manner communicable with the charging unit 11, and has a structure in which the vaporized gas 10v generated by heating the solid feedstock 10s can be extracted. Specifically, the vaporized gas extraction unit 12 is defined as a space partitioned by: the bottom portion of the tank 19 including the bottom surface of the tank 19; and the dispersion plate 13. More specifically, the vaporized gas extraction unit 12 is partitioned into a cylindrical shape in which, for example, the dispersion plate 13 is arranged at an upper portion and the bottom surface of the tank 19 is arranged at a bottom portion. The dispersion plate 13 having a plurality of through holes is interposed between the vaporized gas extraction unit 12 and the charging unit 11. Each of the through holes of the dispersion plate 13 has such a size that powder of the solid feedstock 10s cannot pass through and vaporized gas 10v of the solid feedstock 10s can pass through. With this structure, the vaporized gas extraction unit 12 has the structure communicable with the charging unit 11, and the vaporized gas 10v of the solid feedstock 10s generated inside the charging unit 11 can be extracted. The tank 19 having the charging unit 11 and the vaporized gas extraction unit 12 is housed in an outer container 15.

FIG. 2 is a diagram illustrating an external view of the vaporizer 1 according to the first embodiment. As illustrated in FIG. 2, the outer container 15 has a side surface provided with a window 15w through which a remaining amount of the solid feedstock 10s inside the charging unit 11 can be confirmed. An outer wall surface of the outer container 15 is covered with a tank jacket heater 18b constituting a jacket heater 18. The upper lid 14 is covered with an upper jacket heater 18t constituting the jacket heater 18. The jacket heater 18 has a structure in which the inside of the tank 19 can be heated at a suitable temperature for vaporization of the solid feedstock 10s. Thus, the jacket heater 18 entirely covers the outer container 15 and the upper lid 14, but has a window 18w at a position corresponding to the window 15w of the cuter container 15. The window 18w may be covered with a cap provided with a heater (not illustrated) in order to prevent uneven heating, and the cap can be detached at the time of confirming the remaining amount of the solid feedstock 10s.

The charging unit 11 and the vaporized gas extraction unit 12 are mainly made of transparent quartz. Transparent quartz is quartz that has a property of transmitting light in a range from an ultraviolet region to an infrared region almost without weakening the light and also has transparency to the light in this range. The upper lid 14 and the outer container 15 are made mainly of a metal such as SUS, for example. For example, corrosion resistant coating is applied to a surface of the upper lid 14 located on the charging unit 11 side. The metallic outer container 15 can protect the tank 19 made of relatively fragile quartz but having a relatively large capacity. Additionally, heating and heat-retention effects for the tank 19 by the jacket heater 18 can be enhanced by the outer container 15.

The vaporizer 1 further includes a carrier gas introduction pipe 17 having one end connectable to a carrier gas supply source SRS and the other end inserted into the upper space of the charging unit 11 in which the solid feedstock 10s is charged. The carrier gas introduction pipe 17 is adapted to supply the carrier gas 10c from the carrier gas supply source SRS to the solid feedstock 10s inside the charging unit 11. The carrier gas 10c is a gas serving as a carrier of the vaporized gas 10v to move the vaporized gas 10v, and is an Ar gas, for example. Besides the Ar gas, a rare gas such as a He gas or a Ne gas, or an inert gas such as N₂ gas can be used as a carrier gas. It is preferable that the carrier gas 10c be supplied into the charging unit 11 in a state of being heated to, for example, about 100° C. to 200° C. so as not to hinder vaporization of the solid feedstock 10s by the jacket heater 18. A supply amount of the carrier gas 10c is adjusted such that a constant amount of the vaporized gas 10v is supplied to a substrate processing apparatus APP in consideration of a partial pressure with the vaporized gas 10v. The carrier gas 10c having been supplied into the charging unit 11 is moved toward the vaporized gas extraction unit 12 side inside the solid feedstock 10s. This accelerates movement of the vaporized gas 10v vaporized inside the solid feedstock 10s toward the vaporized gas extraction unit 12 side. A valve 17v is provided at the carrier gas introduction pipe 17. Supply of the carrier gas 10c into the charging unit 11 is started and stopped by opening and closing the valve 17v.

The vaporizer 1 further includes a vaporized gas discharge pipe 16 having one end inserted into the vaporized gas extraction unit 12 and the other end connectable to the substrate processing apparatus APP that is a supply destination of the vaporized gas 10v and processes a substrate. For example, one vaporized gas discharge pipe 16 is provided at a center of the tank 19. More specifically, for example, the vaporized gas discharge pipe 16 passes through the inside of the solid feedstock 10s charged inside the charging unit 11 from an upper surface of the vaporized gas extraction unit 12 and extends from the upper surface of the charging unit 11 to the substrate processing apparatus APP side through the upper space of the charging unit 11. Thus, the vaporized gas discharge pipe 16 can extract the vaporized gas 10v from the vaporized gas extraction unit 12. In other words, the vaporized gas 10v generated inside the charging unit 11 is sucked into the vaporized gas discharge pipe 16 via the vaporized gas extraction unit 12 and then supplied to the substrate processing apparatus APP when the inside of the vaporized gas discharge pipe 16 is vacuumed by depressurization from the substrate processing apparatus APP side. The substrate processing apparatus APP is, for example, a vapor phase epitaxial (deposition) apparatus of Al₂O₃. A valve 16v is provided in the vaporized gas discharge pipe 16. Supply of the vaporized gas 10v to the substrate processing apparatus APP is started and stopped by opening and closing the valve 16v. Additionally, in the vaporized gas discharge pipe 16, corrosion resistant coating is applied to at least a pipe outer wall inside the charging unit 11.

Furthermore, the vaporized gas discharge pipe 16 and the carrier gas introduction pipe 17 are kept within an appropriate temperature range by a tape heater (not illustrated) or the like such that re-solidification due to heat loss, that is, cold trap does not occur.

Note that “the vaporized gas discharge pipe 16 has the other end connectable to the substrate processing apparatus APP” does not necessarily mean that the vaporized gas discharge pipe 16 is directly connected to the substrate processing apparatus APP. The vaporized gas discharge pipe 16 may be connected to a pipe of a facility where the vaporizer 1 is installed, and may be connected to the substrate processing apparatus APP via such a pipe. Additionally, “the carrier gas introduction pipe 17 has one end connectable to the carrier gas supply source SRS” does not necessarily mean that the carrier gas introduction pipe 17 is directly connected to the carrier gas supply source SRS. The carrier gas introduction pipe 17 may be connected to a pipe of a facility where the vaporizer 1 is installed, and may be connected to the carrier gas supply source SRS via such a pipe.

Here, it is preferable that a particle size of the powdery solid feedstock 10s be suitably adjusted. It is preferable that the solid feedstock 10s has the particle size large enough to allow the carrier gas 10c to pass through the inside of the solid feedstock 10s. However, in a case where the particle size of the solid feedstock 10s is excessively large, the carrier gas 10c passes through the inside of the solid feedstock 10s in a very short time, and movement of the vaporized gas 10v inside the solid feedstock 10s is not accelerated. Therefore, it is preferable that the particle size of the solid feedstock 10s is a size enough to allow the carrier gas 10c to pass through the inside of the solid feedstock 10s over an appropriate time.

Meanwhile, for example, AlCl₃ is specified above as the solid feedstock 10s, but different solid feedstock other than AlCl₃ may also be adopted. Examples of the different solid feedstock may include HfCl₄, ZrCl₄, InCl₃, TixIy, Wx(CO)y, Cu, Ga, As, In, Sb, E, P, B₁₀H₁₄, an organometallic β-diketone complex, cyclopentadienyl cycloheptatrienyl titanium (CpTiChT), cyclooctatetraene cyclopentadienyl titanium ((Cot)(Cp)Ti), biscyclopentadienyl titanium diazide, and the like.

Additionally, it is specified above that the supply amount of the vaporized gas 10v to the substrate processing apparatus APP is adjusted by the supply amount of the carrier gas 10c, the supply amount of the vaporized gas 10v may be adjusted by another method. The supply amount of the vaporized gas 10v can also be adjusted by providing a mass flow controller (MFC) in the vaporized gas discharge pipe 16, for example.

Next, vaporization procedures by the vaporizer 1 will be described.

First, the jacket heater 18 is turned on and a suitable temperature for vaporization of solid feedstock 10s is set, and then the solid feedstock 10s is heated. Consequently, the solid feedstock 10s inside the charging unit 11 is partly vaporized, and a vaporized gas 10v is generated.

Additionally, the valve 16v of the vaporized gas discharge pipe 16 is opened, and the inside of the vaporized gas discharge pipe 16 is vacuumed by depressurization from the substrate processing apparatus APP side. Consequently, the inside of the vaporized gas extraction unit 12 is also is vacuumed by depressurization via the vaporized gas discharge pipe 16.

Furthermore, the valve 17v of the carrier gas introduction pipe 17 is opened, and the carrier gas 10c heated to about 100° C. to 200° C. is supplied into the charging unit 11. The carrier gas 10c is sucked to the vaporized gas extraction unit 12 side in the depressurized state, and enters the inside of the solid feedstock 10s in the charging unit 11. At this point, the carrier gas 10c acts as a carrier of the vaporized gas 10v generated in the solid feedstock 10s, and accelerates movement of the vaporized gas 10v toward the vaporized gas extraction unit 12 side.

The vaporized gas 10v and the carrier gas 10c pass through the dispersion plate 13 and flow into the vaporized gas extraction unit 12. The vaporized gas 10v and the carrier gas 10c having flown into the vaporized gas extraction unit 12 are supplied to the substrate processing apparatus APP through the vaporized gas discharge pipe 16.

The vaporizer 1 thus structured can stably vaporize the solid feedstock 10s.

For example, in a case where the vaporizer does not have the vaporized gas extraction unit 12 and the vaporized gas discharge pipe is inserted into the upper space of the tank in a manner similar to the carrier gas introduction pipe, there may be a problem in stable supply of the vaporized gas to the substrate processing apparatus. As described above, the upper space of the tank expands with consumption of the solid feedstock, and the pressure in the upper space is decreased. With this pressure decrease, the supply amount of the vaporized gas to the substrate processing apparatus is also decreased in the vaporizer that extracts the vaporized gas from the upper space of the tank. Thus, in the vaporizer having no vaporized gas extraction unit, a period during which the vaporized gas can be stably supplied is short, and the vaporizer becomes unusable while a large amount of the solid feedstock remains therein. Additionally, in a case where the inside of the vaporizer is made of a metal such as SUS, the tank may be corroded due to the vaporized gas such as AlCl₃ gas. Consequently, metal contamination may be caused during substrate processing inside the substrate processing apparatus.

In the vaporizer 1 of the first embodiment, since the vaporized gas extraction unit 12 is provided at the lower portion of the tank 19, the space from which the vaporized gas 10v is extracted has a constant volume. With this structure, the vaporized gas 10v can be extracted in a state in which influence of pressure fluctuation in the upper space of the charging unit 11 is suppressed, and even in a case where the remaining amount of the solid feedstock 10s is reduced, the supply amount of the vaporized gas 10v to the substrate processing apparatus APP is suppressed from being decreased. Therefore, a period of use of the tank 19 that can stably supply the vaporized gas 10v to the substrate processing apparatus APP is extended, and unused solid feedstock 10s can be reduced. Thus, the vaporizer 1 of the first embodiment can improve consumption efficiency of the vaporized gas 10v.

Furthermore, in the vaporizer 1 of the first embodiment, since a member that may contact the vaporized gas 10v is made of transparent quartz or applied with corrosion resistant coating, corrosion of the tank 19 and the like by the vaporized gas 10v is suppressed, and occurrence of metal contamination inside the substrate processing apparatus APP is suppressed. Additionally, since the charging unit 11 is made of, for example, transparent quartz, the remaining amount of the solid feedstock 10s can be easily visually confirmed.

### Second Embodiment

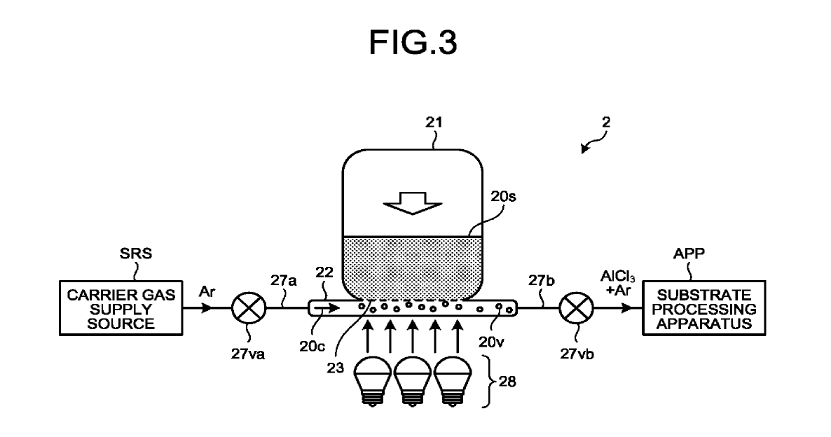

A vaporizer 2 and a vaporized gas supply unit of a second embodiment will be described with reference to FIG. 3.

FIG. 3 is a diagram illustrating an exemplary structure of the vaporizer 2 according to the second embodiment. As illustrated in FIG. 3, the vaporizer 2 includes: a container 21 serving as a charging unit in which solid feedstock 20s that generates a vaporized gas 20v can be charged; and a nozzle 22 serving as a vaporized gas extraction unit, having a side surface joined to a bottom portion of the container 21 in a manner communicable with the container 21, and having one end connectable to a substrate processing apparatus APP that is a supply destination of the vaporized gas 20v. In the following, a structure of the vaporizer 2 will be specifically described.

The container 21 has, for example, a cylindrical shape having an upper surface and also the bottom portion arranged with a dispersion plate 23. A size of the container 21 can be changed in accordance with a charging amount of powdery solid feedstock 20s. The solid feedstock 20s is, for example, AlCl₃. The bottom portion of the container 21 is joined to the side surface of the nozzle 22 extending in a longitudinal direction of the nozzle 22. A width of the nozzle 22 at the portion where the bottom portion of the container 21 is joined is set to a size conforming to a diameter of the bottom portion of the container 21. The container 21 may be joined to the nozzle 22 in a manner detachable from the nozzle 22. Alternatively, the container 21 and the nozzle 22 may be integrally formed.

The dispersion plate 23 having a plurality of through holes is interposed between the container 21 and the nozzle 22. Each of the through holes of the dispersion plate 23 has such a size that powder of the solid feedstock 20s cannot pass through and the vaporized gas 20v of the solid feedstock 20s can pass through. With this structure, the nozzle 22 has a structure communicable with the container 21, and the vaporized gas 20v of the solid feedstock 20s generated inside the container 21 can be extracted.

The nozzle 22 has one end connectable to a carrier gas supply source SRS and the other end connectable to the substrate processing apparatus APP that is the supply destination of the vaporized gas 20v and a carrier gas 20c. In other words, the nozzle 22 is to be inserted into between a carrier gas introduction pipe 27a that supplies the carrier gas 20c and a vaporized gas discharge pipe 27b that discharges the vaporized gas 20v. Here, the nozzle 22 has the one end connectable to the carrier gas introduction pipe 27a on the carrier gas supply source SRS side, and the other end connectable to the vaporized gas discharge pipe 27b on the substrate processing apparatus APP side. More specifically, the carrier gas introduction pipe 27a has one end connected to the carrier gas supply source SRS, and the other end connectable to the one end of the nozzle 22. Additionally, the nozzle 22 has the other end connectable to one end of the vaporized gas discharge pipe 27b, and the vaporized gas discharge pipe 27b has the other end connected to the substrate processing apparatus APP. As the carrier gas 20c, a gas similar to the carrier gas 10c in an above-described first embodiment can be used, including an Ar gas. The carrier gas introduction pipe 27a is provided with a valve 27va that starts and stops supply of the carrier gas 20c to the nozzle 22. The vaporized gas discharge pipe 27b is provided with a valve 27vb that starts and stops supply of the vaporized gas 20v and the carrier gas 20c to the substrate processing apparatus APP.

Additionally, the carrier gas introduction pipe 27a and the vaporized gas discharge pipe 27b are kept within an appropriate temperature range by a tape heater (not illustrated) or the like such that re-solidification due to heat loss, that is, cold trap does not occur.

Note that “the nozzle 22 has the one end connectable to the carrier gas supply source SRS” and “the nozzle 22 has the other end connectable to the substrate processing apparatus APP” do not necessarily mean that the nozzle 22 are directly connected to the carrier gas supply source SRS or the substrate processing apparatus APP As described above, since the nozzle 22 can be inserted into between the carrier gas introduction pipe 27a and the vaporized gas discharge pipe 27b, the nozzle 22 also include a structure indirectly connected to the carrier gas supply source SRS or the substrate processing apparatus APP.

Additionally, “the carrier gas introduction pipe 27a has the one end connected to the carrier gas supply source SRS” does not necessarily mean that the carrier gas introduction pipe 27a is directly connected to the carrier gas supply source SRS. The carrier gas introduction pipe 27a may be connected to a pipe of a facility where the vaporizer 2 is installed, and may be connected to the carrier gas supply source SRS via such a pipe. Additionally, “the vaporized gas discharge pipe 27b has the other end connected to the substrate processing apparatus APP” does not necessarily mean that the vaporized gas discharge pipe 27b is directly connected to the substrate processing apparatus APP. The vaporized gas discharge pipe 27b may be connected to a pipe of a facility where the vaporizer 2 is installed, and may be connected to the substrate processing apparatus APP via such a pipe.

A lamp heater 28 serving as a heating device is arranged below the container 21 and the nozzle 22. The lamp heater 28 can rapidly heat the bottom portion of the container 21 and the solid feedstock 20s at the bottom portion of the container 21 by emitting thermal energy to the container 21. A temperature range obtained by heating of the lamp heater 20 is a suitable temperature for vaporization of the solid feedstock 20s.

The container 21, dispersion plate 23, and nozzle 22 are made of transparent quartz that transmits thermal energy. Transparent quartz is quartz that has a property of transmitting light (heat energy) in a range from an ultraviolet region to an infrared region almost without weakening the light and also has transparency to the light in this range. Consequently, the container 21, dispersion plate 23, and nozzle 22 can transmit thermal energy from the lamp heater 28 to the solid feedstock 20s at the bottom portion of the container 21.

Additionally, for example, AlCl₃ is specified above as the solid feedstock 20s, but different solid feedstock exemplified above one may also be adopted.

Note that a unit (or module) in which the above-described structure can be incorporated in the substrate processing apparatus APP may be deemed as a vaporized gas supply unit that vaporizes the solid feedstock 20s and supplies the same to a space where a substrate is processed. In other words, the vaporized gas supply unit of the second embodiment may include: the nozzle 22 to be inserted into between the carrier gas introduction pipe 27a and the vaporized gas discharge pipe 27b; the container 21 in which the bottom portion is joined to the side surface of the nozzle 22 in a manner communicable with the nozzle 22 and the solid feedstock 20s can be charged; and the lamp heater 28 arranged below the container 21.

Next, vaporization procedures by the vaporizer 2 will be described.

First, the lamp heater 28 is turned on and a suitable temperature for vaporization of the solid feedstock 20s is set. Consequently, the solid feedstock 20s at the bottom portion (portion facing the lamp heater 28) inside the container 21 is vaporized, and the vaporized gas 20v is generated.

Additionally, the valve 27vb of the vaporized gas discharge pipe 27b is opened, and the inside of the vaporized gas discharge pipe 27b is vacuumed by depressurization from the substrate processing apparatus APP side and the inside of the nozzle 22 is vacuumed through the vaporized gas discharge pipe 27b. Consequently, the vaporized gas 20v inside the container 21 flows into the nozzle 22 via the dispersion plate 23.

Additionally, the valve 27va of the carrier gas introduction pipe 27a is opened, and the carrier gas 20c heated to about 100° C. to 200° C. is supplied into the nozzle 22. The carrier gas 20c is supplied to the substrate processing apparatus APP side through the inside of the nozzle 22 and the vaporized gas discharge pipe 27b in the depressurized state. At this point, the carrier gas 20c serves as a carrier of the vaporized gas 20v flowing into the nozzle 22, and accelerates movement of the vaporized gas 20v toward the substrate processing apparatus APP side. Thus, the vaporized gas 20v and the carrier gas 20c are supplied to the substrate processing apparatus APP.

After that, the solid feedstock 20s at the bottom portion of the container 21 is gradually consumed with time. Along with this consumption, the solid feedstock 20s existing at an upper portion of the container 21 is moved down to the bottom portion of the container 21 by own weight, and is newly vaporized by receiving thermal energy from the lamp heater 28. Since only the surface facing the lamp heater 28 is heated, the solid feedstock 20s having a surface area equal to a constant bottom surface area of the container 21 can be vaporized, and a space volume of the nozzle 22 into which the vaporized gas 20v flows is kept constant, and therefore, a stable vapor pressure can be obtained.

The vaporizer 2 having the above-described structure brings effects similar to those in a vaporizer 1 of the first embodiment.

Additionally, since the lamp heater 28 is arranged at the lower portion of the vaporizer 2 of the second embodiment, even in a case where a remaining amount of the solid feedstock 20s is reduced, the solid feedstock 20s gathers toward the heat source by the own weight. Therefore, the solid feedstock 20s can be vaporized more efficiently. Furthermore, thermal efficiency is better than in a case of heating the entire solid feedstock 20s, and power can be saved.

Furthermore, in a case where the container 21 has a small capacity of, for example, about several hundred cc in the vaporizer 2 of the second embodiment, the vaporizer 2 can be installed in the vicinity of the substrate processing apparatus APP. With this structure, the vaporized gas 20v can be supplied to the substrate processing apparatus APP before occurrence of re-solidification (cold trap) caused by heat loss of the vaporized gas 20v during supply of the vaporized gas 20v. Additionally, a frame of the substrate processing apparatus APP can be designed in a more compact size.

Furthermore, since the container 21 is made of transparent quartz in the vaporizer 2 of the second embodiment, the remaining amount of the solid feedstock 20s can be visually confirmed. Additionally, in a case where the container 21 and the nozzle 22 are detachably structured, only the container 21 can be replaced. Alternatively, in a case where the container 21 and the nozzle 22 are integrally formed, the container 21 and the nozzle 22 may be in a structure easily detachable from the carrier gas introduction pipe 27a and the vaporized gas discharge pipe 27b.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A vaporizer comprising:
a charging unit in which solid feedstock that generates a vaporized gas can be charged; and
a vaporized gas extraction unit that is provided at a bottom portion of the charging unit in a manner communicable with the charging unit and extracts the vaporized gas generated by heating the solid feedstock.

2. The vaporizer according to claim 1, further comprising:
a carrier gas introduction pipe that has one end connectable to a carrier gas supply source and the other end inserted into an upper space of the charging unit where the solid feedstock is not charged, and supplies a carrier gas to the solid feedstock inside the charging unit; and
a vaporized gas discharge pipe that has one end inserted into the vaporized gas extraction unit and the other end connectable to a supply destination of the vaporized gas, and extracts the vaporized gas from the vaporized gas extraction unit.

3. The vaporizer according to claim 1, wherein the charging unit and the vaporized gas extraction unit are mainly made of transparent quartz.

4. The vaporizer according to claim 2, wherein the vaporized gas discharge pipe has at least a part of an outer wall applied with corrosion resistant coating.

5. The vaporizer according to claim 3, further comprising an outer container that is made of a metal and houses the charging unit and the vaporized gas extraction unit.

6. The vaporizer according to claim 1, further comprising a heater that is provided around the charging unit and heats the solid feedstock.

7. The vaporizer according to claim 1, wherein the vaporized gas extraction unit is a nozzle having one end connectable to a carrier gas supply source and the other end connectable to a supply destination of the vaporized gas, a side surface of the nozzle communicating with the bottom portion of the charging unit.

8. The vaporizer according to claim 7, wherein the charging unit and the nozzle are mainly made of a material that transmits light emitted from a lamp heater arranged below the charging unit and the nozzle.

9. The vaporizer according to claim 8, wherein the charging unit and the nozzle are mainly made of transparent quartz.

10. The vaporizer according to claim 1, wherein the solid feedstock is made of at least any one of AlCl₃, HfCl₄, ZrCl₄, InCl₃, TixIy, Wx(CO)y, Cu, Ga, As, In, Sb, B, P, B₁₀H₁₄, an organometallic β-diketone complex, cyclopentadienyl cycloheptatrienyl titanium (CpTiChT), cyclooctatetraene cyclopentadienyl titanium ((Cot)(Cp)Ti), and biscyclopentadienyl titanium diazide.

11. A vaporizer comprising:
a tank including: a charging unit in which solid feedstock that generates a vaporized gas can be charged; and a dispersion plate provided on a lower side of the charging unit, the tank having a bottom space formed below the charging unit by partitioning the inside of the tank by the dispersion plate;
a first pipe having one end connectable to a carrier gas supply source and the other end inserted into an upper space of the charging unit of the tank; and
a second pipe having one end inserted into the bottom space of the tank and the other end connectable to a supply destination of the vaporized gas.

12. The vaporizer according to claim 11, wherein
the tank is mainly made of transparent quartz, and
an outer container that is made of a metal and houses the tank is further provided.

13. The vaporizer according to claim 12, wherein the outer container has a side surface provided with a window.

14. The vaporizer according to claim 12, further comprising a heater covering an outer wall surface of the outer container.

15. The vaporizer according to claim 11, wherein the solid feedstock is made of at least any one of AlCl₃, HfCl₄, ZrCl₄, InCl₃, TixIy, Wx(CO)y, Cu, Ga, As, In, Sb, B, P, B₁₀H₁₄, an organometallic β-diketone complex, cyclopentadienyl cycloheptatrienyl titanium (CpTiChT), cyclcoctatetraene cyclopentadienyl titanium ((Cot)(Cp)Ti), and biscyclopentadienyl titanium diazide.

16. A vaporized gas supply unit comprising:
a nozzle to be inserted into a middle of a pipe having one end connectable to a carrier gas supply source and the other end connectable to a gas supply destination;
a charging unit in which a bottom portion thereof is joined to a side surface of the nozzle in a manner communicable with the nozzle and solid feedstock serving as a raw material of a vaporized gas can be charged; and
a heating device arranged below the charging unit.

17. The vaporized gas supply unit according to claim 16, wherein the heating device is a lamp heater.

18. The vaporized gas supply unit according to claim 17, wherein the nozzle and the charging unit are mainly made of a material that transmits light emitted from the lamp heater.

19. The vaporized gas supply unit according to claim 17, wherein the nozzle and the charging unit are mainly made of transparent quartz.

20. The vaporized gas supply unit according to claim 16, wherein the solid feedstock is made of at least any one of AlCl₃, HfCl₄, ZrCl₄, InCl₃, TixIy, Wx(CO)y, Cu, Ga, As, In, Sb, B, P, B₁₀H₁₄, an organometallic β-diketone complex, cyclopentadienyl cycloheptatrienyl titanium (CpTiChT), cyclooctatetraene cyclopentadienyl titanium ((Cot)(Cp)Ti), and biscyclopentadienyl titanium diazide.
